(19) United States
(12) Patent Application Publication
(10) Pub. No.: US 2025/0133792 A1
(43) Pub. Date: Apr. 24, 2025

(54) SWITCHING ELEMENT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: TOSHIKI MII, Nisshin-shi (JP); RYOTA SUZUKI, Nisshin-shi (JP)

(21) Appl. No.: 18/829,395

(22) Filed: Sep. 10, 2024

(30) Foreign Application Priority Data
Oct. 20, 2023 (JP) 2023-181275

(51) Int. Cl. H01L 29/10; H01L 29/06; H01L 29/16; H01L 29/78

(52) U.S. Cl. CPC H10D 62/393; H10D 30/668; H10D 62/10; H10D 62/8325; H10D 84/143

(57) ABSTRACT

A switching element includes trenches extending in a first direction, inter-trench semiconductor layers, and connection regions arranged linearly at intervals along a second direction to form columns. The inter-trench semiconductor layers intersect the columns at intersection portions. The intersection portions include connection intersection portions including connection regions and non-connection intersection portions without the connection regions which are arranged in each of the columns in a pattern in which a portion where the connection intersection portion are arranged continuously and a portion where the non-connection intersection portions are arranged continuously are arranged alternately. A phase of the pattern is shifted in the second direction between the adjacent columns. A Chebyshev distance from each of the non-connection intersection portions to a closest one of the connection intersection portions is 1. A Chebyshev distance from each of the connection intersection portions to a closest one of the non-connection intersection portions is 1.

### CROSS REFERENCE TO RELATED APPLICATION

The present application claims the benefit of priority from Japanese Patent Application No. 2023-181275 filed on Oct. 20, 2023. The entire disclosure of the above application is incorporated herein by reference.

### TECHNICAL FIELD

The present disclosure relates to a switching element.

### BACKGROUND

Conventionally, there have been known trench gate type switching elements including deep layers.

### SUMMARY

The present disclosure provides a switching element including a semiconductor substrate, a gate insulating film, a gate electrode, and a source electrode. The semiconductor substrate has trenches provided from an upper surface of the semiconductor substrate. The trenches extend linearly in a first direction on the upper surface of the semiconductor substrate, and are arranged at intervals in a second direction that intersects the first direction on the upper surface of the semiconductor substrate. The gate insulating film covers an inner surface of each of the trenches. The gate electrode is disposed inside each of the trenches and is insulated from the semiconductor substrate by the gate insulating film. The source electrode is in contact with the upper surface of the semiconductor substrate. The semiconductor substrate includes inter-trench semiconductor layers sandwiched between each of the trenches. Each of the inter-trench semiconductor layers includes a source region of n-type being in contact with the gate insulating film and the source electrode, and a body region of p-type being in contact with the gate insulating film at a position below the source region. The semiconductor substrate further includes a drift region of n-type, deep regions of p-type, and connection regions of p-type. The drift region is distributed over a lower portion of each of the inter-trench semiconductor layers and is in contact with the gate insulating film at a position below the body region in each of the inter-trench semiconductor layers. The deep regions are disposed in a range surrounded by the drift region, disposed below the body region to be spaced apart from the body region, and disposed in a range including a lower end of each of the trenches or below the lower end of each of the trenches in a thickness direction of the semiconductor substrate. The connection regions connect the body region and the deep regions. When the semiconductor substrate is viewed from above, the connection regions are arranged linearly at intervals along the second direction to form columns, and the columns are arranged at intervals in the first direction. When the semiconductor substrate is viewed from above, the inter-trench semiconductor layers intersect the columns at intersection portions. The intersection portions include connection intersection portions at which the connection regions are disposed and non-connection intersection portions at which the connection regions are not disposed. The connection intersection portions and the non-connection intersection portions are arranged so as to satisfy following conditions (i) to (iv):
(i) in each of the columns, the connection intersection portions and the non-connection intersection portions are arranged in a pattern in which a portion where the connection intersection portions of a first reference number, which is 2 or greater, are arranged continuously and a portion where the non-connection intersection portions of a second reference number, which is 2 or greater, are arranged continuously are arranged alternately in the second direction;
(ii) a phase of the pattern is shifted in the second direction between adjacent columns in the columns;
(iii) when counting a Chebyshev distance in units of each of the intersection portions, the Chebyshev distance from each of the non-connection intersection portions to a closest one of the connection intersection portions is 1; and
(vi) when counting a Chebyshev distance in units of each of the intersection portions, the Chebyshev distance from each of the connection intersection portions to a closest one of the non-connection intersection portions is 1.

### BRIEF DESCRIPTION OF DRAWINGS

Objects, features and advantages of the present disclosure will become apparent from the following detailed description made with reference to the accompanying drawings. In the drawings:

FIG. 1 is a perspective view including cross sections along an x direction and a y direction of a switching element according to a first embodiment;

FIG. 2 is a cross-sectional view illustrating a cross section along the y direction at a position including a deep region, which corresponds to a position of line II-II in FIG. 6, of the switching element according to the first embodiment;

FIG. 3 is a cross-sectional view illustrating a cross section along the y direction at a position not including the deep region, which corresponds to a position of line III-III in FIG. 6, of the switching element according to the first embodiment;

FIG. 4 is a cross-sectional view illustrating a cross section along the x direction at a position not including trenches, which corresponds to a position of line IV-IV in FIG. 6, of the switching element according to the first embodiment;

FIG. 5 is a cross-sectional view illustrating a cross section along the x direction at a position including trenches, which corresponds to a position of line V-V in FIG. 6, of the switching element according to the first embodiment;

FIG. 6 is a plan view illustrating an arrangement of connection intersection portions of the switching element according to the first embodiment;

FIG. 7 is a layout diagram of the connection intersection portions according to the first embodiment;

FIG. 8 is a layout diagram of connection intersection portions of a first comparative example;

FIG. 9 is a layout diagram of connection intersection portions of a second comparative example;

FIG. 10 is a perspective view including cross sections along an x direction and a y direction of a switching element according to a second embodiment;

FIG. 11 is a plan view illustrating an arrangement of connection intersection portions of the switching element according to the second embodiment;

FIG. 12 is a perspective view including cross sections along an x direction and a y direction of a switching element according to a third embodiment;

FIG. 13 is a plan view illustrating an arrangement of connection intersection portions of the switching element according to the third embodiment;

FIG. 14 is a perspective view including cross sections along an x direction and a y direction of a switching element according to a fourth embodiment;

FIG. 15 is a plan view showing an arrangement of connection intersection portions of the switching element according to the fourth embodiment;

FIG. 16 is a perspective view including cross sections along an x direction and a y direction of a switching element according to another embodiment;

FIG. 17 is a layout diagram illustrating variations in arrangement of connection intersection portions that satisfy conditions (i) to (iv) when A=B;

FIG. 18 is a layout diagram illustrating variations in arrangement of connection intersection portions that satisfy conditions (i) to (iv) when A<B;

FIG. 19 is a layout diagram illustrating variations in arrangement of connection intersection portions that satisfy conditions (i) to (iv) when A>B; and

FIG. 20 is a layout diagram illustrating arrangements of connection intersection portions when a shift amount changes.

### DETAILED DESCRIPTION

Next, a relevant technology is described only for understanding the following embodiments. A switching element according to the relevant technology includes multiple deep layers of p-type inside a drift layer of n-type. Each of the deep layers is disposed below lower ends of trenches in a thickness direction of a semiconductor substrate. The switching element further includes multiple connection regions of p-type. Each of the connection regions connects each of the deep layers to a body layer of p-type. When the deep layers and the connection regions are disposed in the above-described manner, an electric field applied to gate insulating films covering the lower ends of the trenches can be restricted.

In the above-described switching element, when the semiconductor substrate is viewed from above, the connection regions are arranged in a distributed manner so as to be kept at predetermined intervals in an x direction and a y direction. That is, when the semiconductor substrate is viewed from above, the connection regions are arranged in the dispersed manner. When the connection regions are arranged in the dispersed manner, a wide channel is ensured.

Inside the switching element, a diode (so-called body diode) is configured by an interface between the body layer of p-type and the drift layer of n-type. When a voltage applied to the body diode is switched from a forward direction to a reverse direction, a recovery current flows through the switching element, and a recovery surge occurs. When the density of the connection regions is low as in the above-described switching element, the recovery surge can be restricted.

However, during operation of the switching element, a recovery current or an avalanche current may flow from the drift region to each of the connection regions. In the above-described switching element, when the recovery current or the avalanche current flows in the drift region, the current is likely to concentrate in the vicinity of each of the connection regions.

Furthermore, in the above-described switching element, an independent connection region is provided for each semiconductor layer sandwiched between trenches (hereinafter, also referred to as inter-trench semiconductor layer). However, when the trenches are arranged at a high density, the width of the inter-trench semiconductor layer becomes narrow, making it difficult to form an independent connection region for each inter-trench semiconductor layer.

A switching element according to one aspect of the present disclosure includes a semiconductor substrate, a gate insulating film, a gate electrode, and a source electrode. The semiconductor substrate has trenches provided from an upper surface of the semiconductor substrate. The trenches extend linearly in a first direction on the upper surface of the semiconductor substrate, and are arranged at intervals in a second direction that intersects the first direction on the upper surface of the semiconductor substrate. The gate insulating film covers an inner surface of each of the trenches. The gate electrode is disposed inside each of the trenches and is insulated from the semiconductor substrate by the gate insulating film. The source electrode is in contact with the upper surface of the semiconductor substrate. The semiconductor substrate includes inter-trench semiconductor layers sandwiched between each of the trenches. Each of the inter-trench semiconductor layers includes a source region of n-type being in contact with the gate insulating film and the source electrode, and a body region of p-type being in contact with the gate insulating film at a position below the source region. The semiconductor substrate further includes a drift region of n-type, deep regions of p-type, and connection regions of p-type. The drift region is distributed over a lower portion of each of the inter-trench semiconductor layers and is in contact with the gate insulating film at a position below the body region in each of the inter-trench semiconductor layers. The deep regions are disposed in a range surrounded by the drift region, disposed below the body region to be spaced apart from the body region, and disposed in a range including a lower end of each of the trenches or below the lower end of each of the trenches in a thickness direction of the semiconductor substrate. The connection regions connect the body region and the deep regions. When the semiconductor substrate is viewed from above, the connection regions are arranged linearly at intervals along the second direction to form columns, and the columns are arranged at intervals in the first direction. When the semiconductor substrate is viewed from above, the inter-trench semiconductor layers intersect the columns at intersection portions. The intersection portions include connection intersection portions at which the connection regions are disposed and non-connection intersection portions at which the connection regions are not disposed. The connection intersection portions and the non-connection intersection portions are arranged so as to satisfy following conditions (i) to (iv):
(i) in each of the columns, the connection intersection portions and the non-connection intersection portions are arranged in a pattern in which a portion where the connection intersection portions of a first reference number, which is 2 or greater, are arranged continuously and a portion where the non-connection intersection portions of a second reference number, which is 2 or greater, are arranged continuously are arranged alternately in the second direction;
(ii) a phase of the pattern is shifted in the second direction between adjacent columns in the columns;
(iii) when counting a Chebyshev distance in units of each of the intersection portions, the Chebyshev distance from each of the non-connection intersection portions to a closest one of the connection intersection portions is 1; and
(vi) when counting a Chebyshev distance in units of each of the intersection portions, the Chebyshev distance from each of the connection intersection portions to a closest one of the non-connection intersection portions is 1.

In the switching element according to the one aspect, the connection intersection portions of the first reference number, which is 2 or greater, are arranged continuously in the second direction. That is, the connection intersection portions are provided across 2 or more inter-trench semiconductor layers. Therefore, even if the width of the inter-trench semiconductor layer is narrow, the connection intersection portions can be appropriately formed.

Furthermore, when the connection intersection portions are densely arranged, the connection regions located at the center of the dense area makes little contribution to stabilizing the potential of the deep layers. If such unnecessary connection regions exist, the number of channels is reduced by the amount of the unnecessary connection regions. In contrast, in the switching element according to the one aspect, when the Chebyshev distance is counted in units of each of the intersection portions, the Chebyshev distance from each of the connection intersection portions to the closest one of the non-connection intersection portions is 1. That is, the congestion of the connection intersection portions is restricted. Therefore, in the switching element according to the one aspect, a wide channel can be ensured.

Furthermore, if there is a non-connection intersection portion that is extremely far from the connection intersection portions, a recovery current and an avalanche current are unlikely to flow in the vicinity of the non-connection intersection portion that is extremely far from the connection intersection portions. In this case, the density of the recovery current and the avalanche current increases in the vicinity of the connection regions. In contrast, in the switching element according to the one aspect, when the Chebyshev distance is counted in units of each of the intersection portions, the Chebyshev distance from each of the non-connection intersection portions to the closest one of the connection intersection portions is 1. That is, there is no non-connection intersection portion having an extremely long distance to the closest one of the connection intersection portions. Therefore, in this switching element, a current concentration in the vicinity of each of the connection regions is restricted.

In the switching element according to the one aspect, the second reference number may be equal to or greater than the first reference number.

According to this configuration, the connection intersection portions of a small number can be efficiently distributed and arranged.

In the switching element according to the one aspect, in each of the inter-trench semiconductor layers, the connection intersection portions may be arranged so as not to be continuous in the first direction when viewed in units of each of the intersection portions.

According to this configuration, the connection intersection portions can be arranged in a more dispersed manner.

In the switching element according to the one aspect, in each of the inter-trench semiconductor layers, the number of the connection intersection portions that are arranged continuously in the first direction when viewed in units of each of the intersection portions may be 3 or less.

According to this configuration, the connection intersection portions can be arranged in a more dispersed manner.

In the switching element according to the one aspect, when the first reference number is expressed as any integer A, the second reference number may be 3A. In the columns, the phase of the pattern may change periodically every four columns. The four columns may be designated as a first column, a second column, a third column, and a fourth column in order, and when a shift amount of the phase of the pattern is counted in units of each of the intersection portions, the shift amount of the second column with respect to the first column may be A, the shift amount of the third column with respect to the first column may be 3A, and the shift amount of the fourth column with respect to the first column may be 2A.

According to this configuration, the connection intersection portions can be arranged in a dispersed manner.

In the switching element according to the one aspect, the deep regions extend linearly along the second direction and are arranged at intervals in the first direction so that the deep regions extend along the columns, respectively, when the semiconductor substrate is viewed from above.

In the switching element according to the one aspect, contact regions of p-type that connect the body region and the source electrode may be disposed above the connection regions.

### First Embodiment

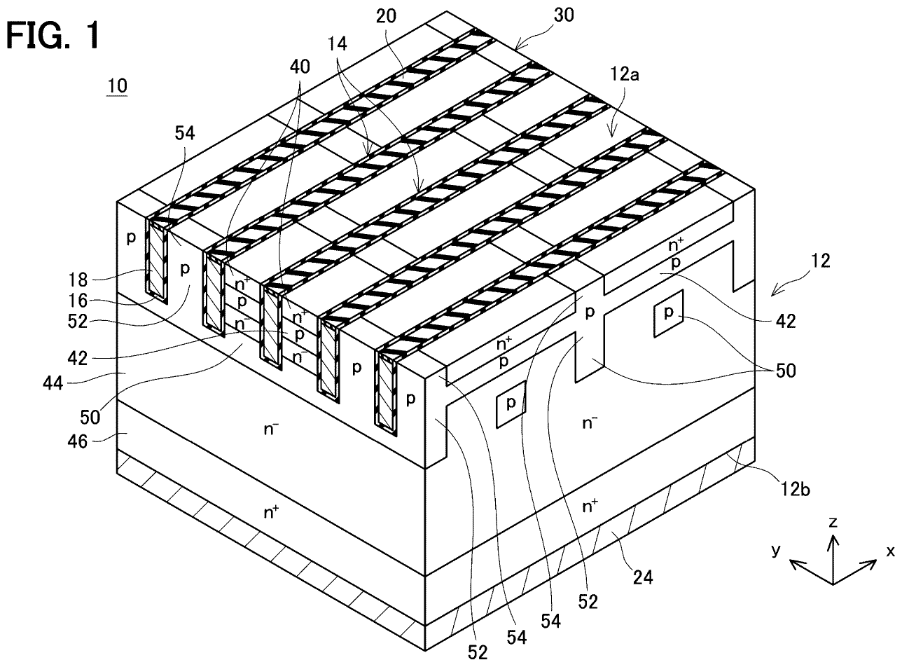

A switching element 10 according to a first embodiment of the present disclosure includes a semiconductor substrate 12 as illustrated in FIG. 1. The semiconductor substrate 12 is made of silicon carbide (SiC). However, the semiconductor substrate 12 may be made of another semiconductor such as silicon (Si) or gallium nitride (GaN). In the following, a direction parallel to an upper surface 12a of the semiconductor substrate 12 is referred to as an x direction, a direction parallel to the upper surface 12a and perpendicular to the x direction is referred to as a y direction, and a thickness direction of the semiconductor substrate 12 is referred to as a z direction. Multiple trenches 14 are provided from the upper surface 12a of the semiconductor substrate 12. Each of the trenches 14 extends linearly in the x direction on the upper surface 12a. The trenches 14 are arranged at intervals in the y direction on the upper surface 12a. An inner surface of each of the trenches 14 is covered with a gate insulating film 16. A gate electrode 18 is disposed in each of the trenches 14. The gate electrode 18 is insulated from the semiconductor substrate 12 by the gate insulating film 16. An interlayer insulating film 20 is disposed in each of the trenches 14. The interlayer insulating film 20 covers an upper surface of the gate electrode 18.

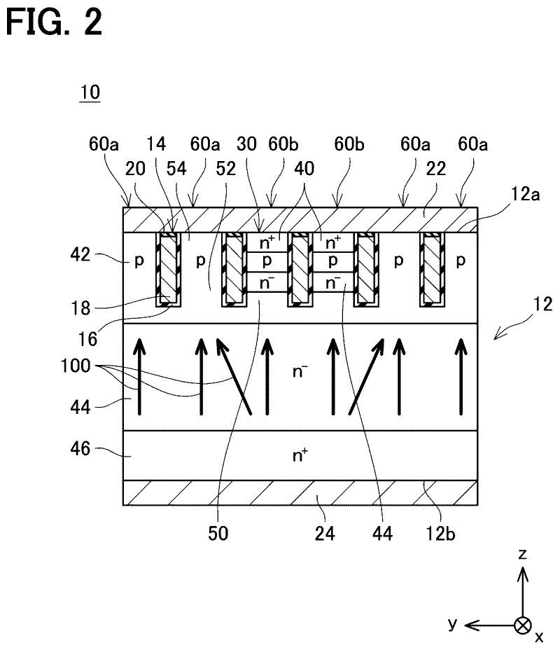

As illustrated in FIGS. 2 to 5, a source electrode 22 is disposed above the semiconductor substrate 12. In FIG. 1, illustration of the source electrode 22 is omitted. The source electrode 22 covers upper surfaces of the interlayer insulating films 20 and the upper surface 12a of the semiconductor substrate 12. The source electrode 22 is insulated from the gate electrodes 18 by the interlayer insulating films 20. A drain electrode 24 is disposed under the semiconductor substrate 12. The drain electrode 24 covers a lower surface 12b of the semiconductor substrate 12.

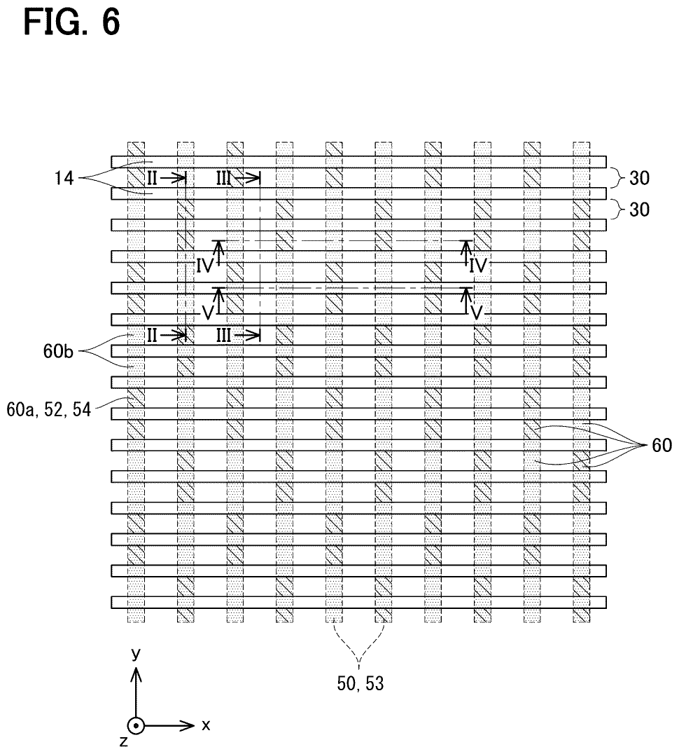

FIG. 6 illustrates the upper surface 12a of the semiconductor substrate 12. As described above, the trenches 14 extending linearly in the x direction are arranged at intervals in the y direction on the upper surface 12a. An inter-trench semiconductor layer 30 illustrated in FIG. 6 is a semiconductor layer sandwiched between the adjacent trenches 14. Each of the inter-trench semiconductor layers 30 extends linearly in the x direction on the upper surface 12a. The inter-trench semiconductor layers 30 are arranged at intervals in the y direction on the upper surface 12a.

As illustrated in FIG. 1, the semiconductor substrate 12 includes a source region 40, a body region 42, a drift region 44, and a drain region 46.

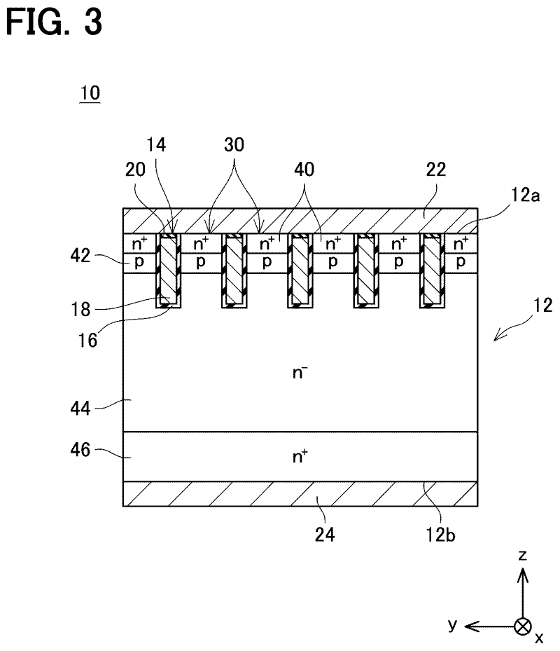

The source region 40 is an n-type region having a high n-type impurity concentration. The source region 40 is disposed in the inter-trench semiconductor layer 30. As illustrated in FIGS. 2 and 3, the source region 40 is in contact with the source electrode 22 in the inter-trench semiconductor layer 30. The source region 40 is in contact with the gate insulating films 16 on side surfaces of the trenches 14 provided on both sides of the inter-trench semiconductor layer 30.

The body region 42 is a p-type region having a low p-type impurity concentration. The body region 42 is disposed in the inter-trench semiconductor layer 30. As illustrated in FIG. 2 and FIG. 3, the body region 42 is disposed in the inter-trench semiconductor layer 30 and is disposed below the source region 40. The body region 42 is in contact with the gate insulating films 16 at positions below the source region 40. That is, the body region 42 is in contact with the gate insulating films 16 on the side surfaces of the trenches 14 provided on both sides of the inter-trench semiconductor layer 30.

The drift region 44 is an n-type region having a low n-type impurity concentration. As illustrated in FIG. 2 and FIG. 3, the drift region 44 is distributed over lower portions of the inter-trench semiconductor layers 30. As illustrated in FIG. 3, an upper end portion of the drift region 44 extends into each of the inter-trench semiconductor layers 30. The drift region 44 is in contact with the body region 42 from below in each of the inter-trench semiconductor layers 30. The drift region 44 is in contact with the gate insulating films 16 at positions below the body region 42. That is, the drift region 44 is in contact with the gate insulating films 16 on the side surfaces of the trenches 14 provided on both sides of each of the inter-trench semiconductor layers 30.

The drain region 46 is an n-type region having a high n-type impurity concentration. The n-type impurity concentration of the drain region 46 is higher than the n-type impurity concentration of the drift region 44. As illustrated in FIGS. 2 to 5, the drain region 46 is in contact with the drift region 44 from below. The drain region 46 is in contact with the drain electrode 24 on the lower surface 12b of the semiconductor substrate 12.

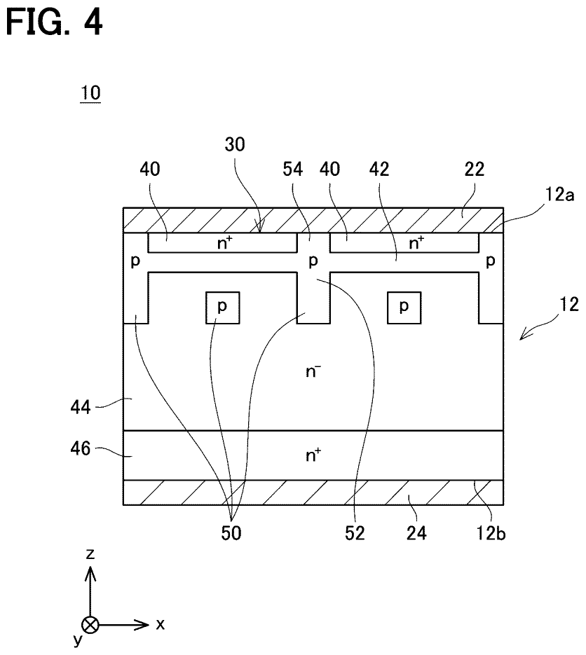

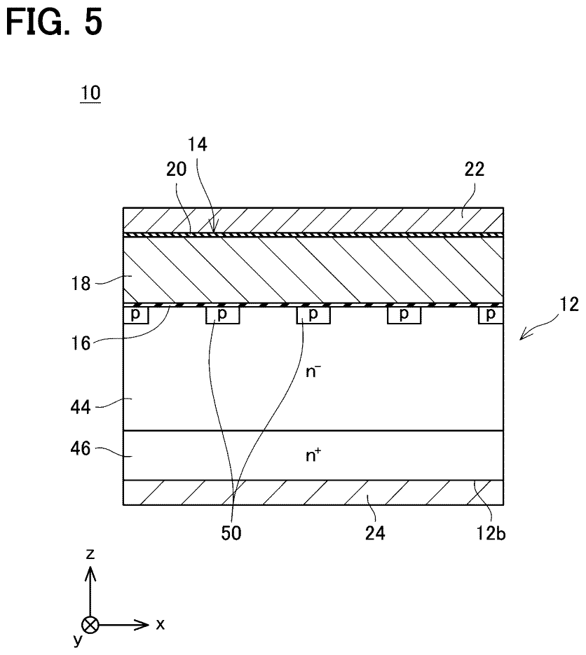

The semiconductor substrate 12 includes multiple deep regions 50 of p-type. As illustrated in FIG. 2 and FIG. 4, each of the deep regions 50 is disposed in a range surrounded by the drift region 44. Each of the deep regions 50 is disposed below the body region 42 to be spaced apart from the body region 42. The drift region 44 is distributed in a region located between each of the deep regions 50 and the body region 42. In FIG. 6, dot-hatched regions indicate a distribution range of the deep regions 50. As illustrated in FIG. 6, when the semiconductor substrate 12 is viewed from above, each of the deep regions 50 extends linearly in the y direction. When the semiconductor substrate 12 is viewed from above, the deep regions 50 are arranged at intervals in the x direction. As illustrated in FIG. 1, FIG. 2, and FIG. 5, each of the deep regions 50 is arranged in a range including lower ends of the trenches 14 in the z direction. Therefore, each of the deep regions 50 is in contact with the gate insulating films 16 at the lower ends of the trenches 14.

As illustrated in FIG. 1, the semiconductor substrate 12 includes multiple connection regions 52 and multiple contact regions 54. As illustrated in FIG. 1, FIG. 2, and FIG. 4, the connection regions 52 are p-type regions that connect the body region 42 and the deep regions 50. The connection regions 52 are provided in each of the inter-trench semiconductor layers 30. The contact regions 54 are p-type regions that connect the body region 42 and the source electrode 22. That is, the contact regions 54 extend upward from the body region 42 and are in contact with the source electrode 22 at upper ends thereof. The contact regions 54 is provided in each of the inter-trench semiconductor layers 30. In the present embodiment, the contact regions 54 and the connection regions 52 continuously extend in the z direction. That is, each of the contact regions 54 is disposed above corresponding one of the connection regions 52. The semiconductor substrate 12 includes multiple sets of the contact region 54 and the deep region 50. Each of the deep regions 50 is connected to the source electrode 22 via the connection regions 52 and the contact regions 54.

Hatched regions in FIG. 6 indicate sets of the connection region 52 and the contact region 54. The sets of the connection region 52 and the contact region 54 are partially provided above the deep regions 50. As illustrated in FIG. 6, when the semiconductor substrate 12 is viewed from above, the connection regions 52 are arranged so as to form multiple columns 53 extending linearly in the y direction. In FIG. 6, the columns 53 extending in the y direction overlap the deep regions 50. The columns 53 are arranged at intervals in the x direction.

Intersection portions 60 illustrated in FIG. 6 are portions where the inter-trench semiconductor layers 30 and the columns 53 intersect with each other when the semiconductor substrate 12 is viewed from above. In the first embodiment, the intersection portions 60 coincide with portions where the inter-trench semiconductor layers 30 and the deep regions 50 intersect with each other when the semiconductor substrate 12 is viewed from above. As described above, each of the inter-trench semiconductor layers 30 extends linearly in the x direction, and each of the columns 53 extends linearly in the y direction. Therefore, when the semiconductor substrate 12 is viewed from above, the intersection portions 60 are arranged in a matrix along the x direction and the y direction. As illustrated in FIG. 6, the sets of the connection region 52 and the contact region 54 are provided in a part of the intersection portions 60. As illustrated in FIG. 1, FIG. 2, and FIG. 6, each of the connection regions 52 is in contact with the gate insulating films 16 on the side surfaces of the trenches 14 located on both sides of the intersection portions 60. In addition, each of the contact regions 54 is in contact with the gate insulating films 16 on the side surfaces of the trenches 14 located on both sides of the intersection portions 60. Hereinafter, the intersection portions 60 in which the connection regions 52 are disposed are referred to as connection intersection portions 60a, and the intersection portions 60 in which the connection regions 52 are not disposed are referred to as non-connection intersection portions 60b.

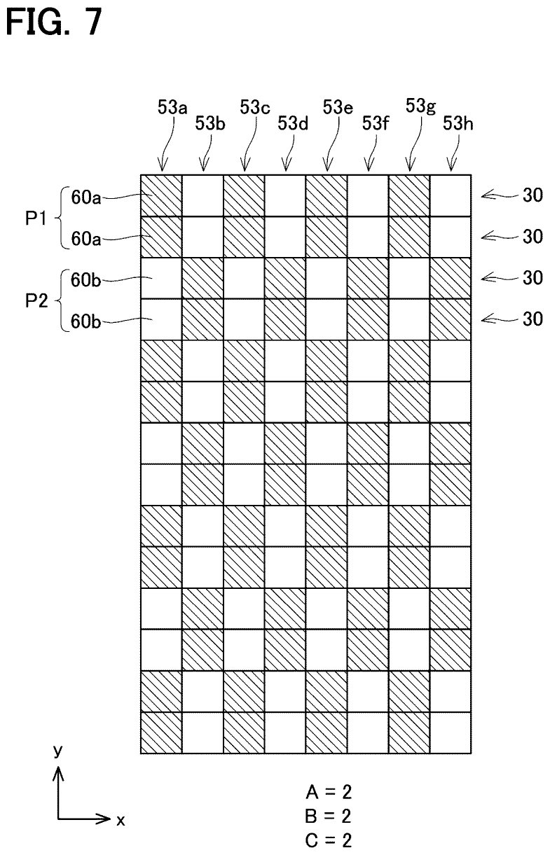

FIG. 7 shows a layout diagram of the connection intersection portions 60a and the non-connection intersection portions 60b. Each cell in FIG. 7 indicates the intersection portion 60. Hatched cells in FIG. 7 represent the connection intersection portions 60a, and blank cells in FIG. 7 represent the non-connection intersection portions 60b. In FIG. 7, the columns 53 are indicated as columns 53a, 53b, 53c, 53d, 53e, 53f, 53g, and 53h from the left. The connection intersection portions 60a and the non-connection intersection portions 60b are arranged so as to satisfy the following conditions (i) to (vi).

(i) In each of the columns 53, a portion P1 where the connection intersection portions 60a of a first reference number A, which is 2 or greater, are arranged continuously and a portion P2 where the non-connection intersection portions 60b of a second reference number B, which is 2 or greater, are arranged continuously are arranged alternately in the y direction, so that the connection intersection portions 60a and the non-connection intersection portions 60b are arranged in a repeating pattern.

(ii) Between the adjacent columns 53, a phase of the repeating pattern is shifted in the y direction.

(iii) When counting a Chebyshev distance in units of each of the intersection portions 60, the Chebyshev distance from each the non-connection intersection portions 60b to the closest one of the connection intersection portions 60a is 1.

(vi) When counting a Chebyshev distance in units of each of the intersection portions 60, the Chebyshev distance from each of the connection intersection portions 60a to the closest one of the non-connection intersection portions 60b is 1.

FIG. 7 shows a case where the first reference number A is 2 and the second reference number B is 2. In FIG. 7, the connection intersection portions 60a and the non-connection intersection portions 60b are arranged in such a manner that the phase of the repeating pattern is shifted downward by a constant amount as a column shifts rightward from the column 53a. Hereinafter, the amount of the phase shift when the phase of the repeating pattern shifts downward by the constant amount as the column shifts rightward is referred to as a shift amount C. The shift amount C is counted in units of cells (that is, in units of each of the intersection portions 60). FIG. 7 shows a case where the shift amount C is 2. That is, the phase of the repeating pattern in the column 53b is shifted downward by two cells with respect to the column 53a, and the phase of the repeating pattern in the column 53c is shifted downward by two cells with respect to the column 53b. In FIG. 7, each of the non-connection intersection portions 60b is adjacent to at least one of the connection intersection portions 60a. Therefore, for all of the non-connection intersection portions 60b, the Chebyshev distance from each of the non-connection intersection portions 60b to the closest one of the connection intersection portions 60a is 1. In addition, in FIG. 7, each of the connection intersection portions 60a is adjacent to at least one of the non-connection intersection portions 60b. Therefore, for all of the connection intersection portions 60a, the Chebyshev distance from each of the connection intersection portions 60a to the closest one of the non-connection intersection portion 60b is 1.

The switching element 10 of the first embodiment is a so-called metal-oxide-semiconductor field effect transistor (MOSFET). In a normal state, a potential higher than a potential of the source electrode 22 is applied to the drain electrode 24. When a potential higher than a gate threshold value is applied to the gate electrodes 18, inversion layers are formed in the body regions 42. At the non-connection intersection portions 60b, the source regions 40 and the drift regions 44 are connected by the inversion layers formed in the body regions 42. As a result, the switching element 10 is turned on, and a current flows from the drain electrode 24 to the source electrode 22. Thus, the inversion layers formed in the non-connection intersection portions 60b function as channels. On the other hand, at the connection intersection portions 60a, the contact regions 54 and the connection regions 52 are disposed above and below the body regions 42. Therefore, in the connection intersection portions 60a, almost no current flows through the inversion layers formed in the body regions 42. That is, the inversion layers formed in the connection intersection portions 60a do not function as channels. As described above, when a high potential is applied to the gate electrodes 18, the inversion layers formed at the non-connection intersection portions 60b function as the channels, and the switching element 10 is turned on.

When the potential of the gate electrodes 18 is reduced to a potential lower than the gate threshold value, the inversion layers disappear and the switching element 10 is turned off. When the switching element 10 is turned off, a reverse voltage is applied to pn junctions at interfaces between the body regions 42 and the drift region 44, and depletion layer spread from the body regions 42 to the drift region 44. In addition, the connection regions 52 are provided to stabilize the potential of the deep regions 50 with the potential of the body regions 42. In other words, the potential of the deep regions 50 is approximately equal to the potential of the body regions 42 because the deep regions 50 are connected to the body regions 42 by the connection regions 52. Therefore, a reverse voltage is applied to pn junctions at interfaces between the deep regions 50 and the drift region 44, and depletion layers spread from the deep regions 50 to the drift region 44. The depletion layers extending from the deep regions 50 restrict a high electric field from being applied to the gate insulating films 16 at lower end portions of the trenches 14.

There may be a case where a potential higher than the potential of the drain electrode 24 is applied to the source electrode 22. In this case, diodes (so-called body diodes) formed by the pn junctions at the interfaces between the body regions 42 and the drift region 44 are turned on, and a current flows from the source electrode 22 to the drain electrode 24. In a state where the body diodes are in on-state, holes flow from the body regions 42 into the drift region 44. Thus many holes are present in the drift region 44. Thereafter, when the potential of the drain electrode 24 becomes higher than the potential of the source electrode 22, the body diodes are turned off. Then, holes present in the drift region 44 flow to the deep regions 50 as indicated by arrows 100 in FIG. 2. The holes flowing from the drift region 44 into the deep regions 50 flow to the source electrode 22 via the connection regions 52 and the contact regions 54. The current generated when the body diodes are turned off in this manner is called a recovery current. As illustrated in FIG. 2, in the connection intersection portions 60a where the connection regions 52 are disposed, the recovery current flows more easily to the drift region 44 than in the non-connection intersection portions 60b where the connection regions 52 are not disposed.

In addition, there may be a case where an overvoltage is applied to the switching element 10 in a direction in which the drain electrode 24 has a higher potential than the source electrode 22. In this case, an avalanche current is generated in the drift region 44. The avalanche current flows to the deep regions 50 as indicated by the arrows 100 in FIG. 2. The avalanche current flowing from the drift region 44 into the deep regions 50 flows to the source electrode 22 via the connection regions 52 and the contact regions 54. As illustrated in FIG. 2, in the connection intersection portions 60a where the connection regions 52 are provided, the avalanche current more easily flows to the drift region 44 than in the non-connection intersection portions 60b where the connection regions 52 are not provided.

As described above, in the connection intersection portions 60a, the recovery current and the avalanche current are more likely to flow in the drift region 44 than in the non-connection intersection portions 60b. In the non-connection intersection portions 60b, the recovery current and the avalanche current are less likely to flow with increase in the distance to the connection intersection portions 60a. If there is the non-connection intersection portions 60b through which the recovery current and the avalanche current are less likely to flow, the recovery current and the avalanche current tend to concentrate at the connection intersection portions 60a.

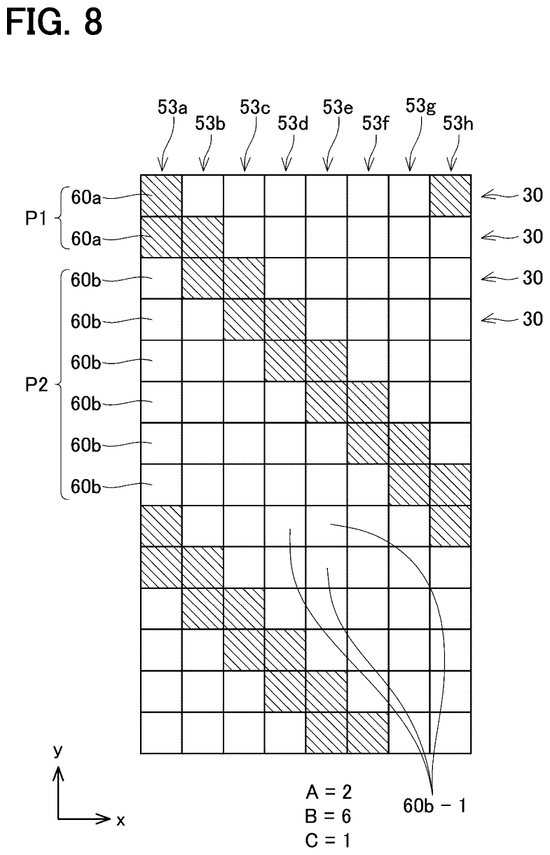

FIG. 8 shows an arrangement of the connection intersection portions 60a and the non-connection intersection portions 60b of a switching element of a first comparative example. In the arrangement shown in FIGS. 8, A=2, B=6, and C=1. In the arrangement of FIG. 8, a Chebyshev distance from each of non-connection intersection portions 60b-1 to the closest one of the connection intersection portion 60a is 2. That is, the arrangement shown in FIG. 8 does not satisfy the above condition (iii). At the non-connection intersection portions 60b-1, which has a long Chebyshev distance to the closest one of the connection intersection portions 60a, the recovery current and the avalanche current are extremely less likely to flow. For this reason, in the arrangement shown in FIG. 8, the recovery current and the avalanche current tend to concentrate at the connection intersection portions 60a. Thus, the switching element of the first comparative example has low recovery resistance and low avalanche resistance. In contrast, in the switching element 10 of the first embodiment, as shown in FIG. 7, for all of the non-connection intersection portions 60b, the Chebyshev distance to the closest one of the connection intersection portions 60a is 1. Therefore, in the switching element 10 according to the first embodiment, the concentration of the recovery current and the avalanche current is less likely to occur at the connection intersection portions 60a. Therefore, the switching element 10 of the first embodiment has high recovery resistance and high avalanche resistance. Therefore, according to the structure of the switching element 10 of the first embodiment, it is possible to realize higher reliability.

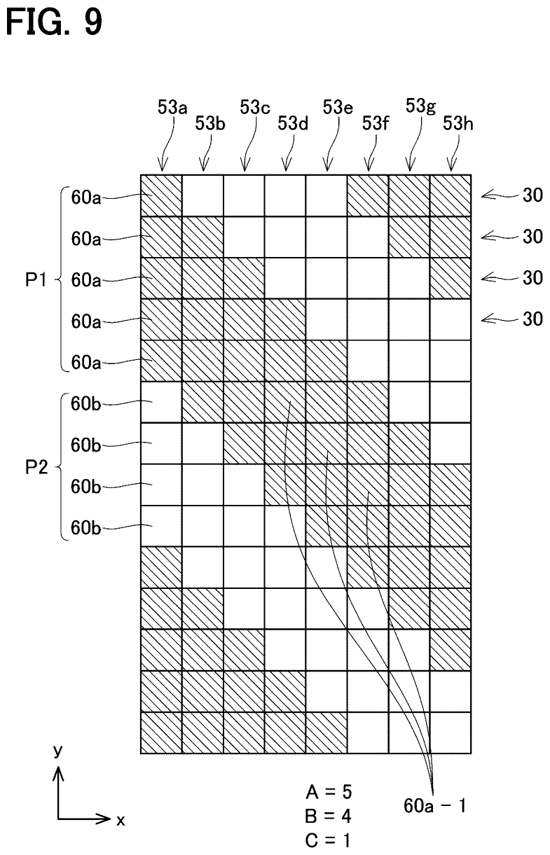

FIG. 9 shows the arrangement of the connection intersection portions 60a and the non-connection intersection portions 60b of a switching element of a second comparative example. In the arrangement shown in FIGS. 9, A=5, B=4, and C=1. In the arrangement of FIG. 9, the Chebyshev distance from connection intersection portions 60a-1 to the closest one of the non-connection intersection portions 60b is 2. That is, in FIG. 9, the connection intersection portions 60a are densely arranged, and the connection intersection portions 60a-1 are located at the center of the densely arranged area. As described above, the connection regions 52 (that is, the connection intersection portions 60a) are provided to stabilize the potential of the deep regions 50 with the potential of the body regions 42. In the area where the connection intersection portions 60a are densely arranged, the deep regions 50 are connected to the body regions 42 by a large number of connection intersection portions 60a, so that the connection intersection portions 60a-1 located in the center of the area where the connection intersection portions 60a are densely arranged contribute little to stabilizing the potential of the deep regions 50. If such an unnecessary connection intersection portion 60a-1 exists, the channel density decreases and the on-resistance of the switching element increases. In contrast, in the switching element 10 of the first embodiment, as shown in FIG. 7, for all of the connection intersection portions 60a, the Chebyshev distance to the closest one of the non-connection intersection portions 60b is 1. Therefore, in the switching element 10 of the first embodiment, all of the connection intersection portions 60a contribute to stabilizing the potential of the deep region 50, and no unnecessary connection intersection portions 60a exist. Therefore, it is possible to provide channels at a high density. Therefore, according to the structure of the switching element 10 of the first embodiment, a low on-resistance can be achieved.

Furthermore, in recent years, the interval between the trenches 14 has become narrower in order to increase the current density (that is, channel density) of the switching element. That is, the width of the inter-trench semiconductor layer 30 is narrowed. For this reason, it may be difficult to form the connection region 52 and the contact region 54 for each inter-trench semiconductor layer 30. In contrast, in the first embodiment, the connection intersection portions 60a are arranged so as to be continuous in the y direction for the first reference number A (that is, 2 or greater), so that the connection regions 52 and the contact regions 54 can be formed across multiple inter-trench semiconductor layers 30. Therefore, even if the width of the inter-trench semiconductor layer 30 is narrow, the connection region 52 and the contact region 54 can be easily formed. For example, even if the width of the inter-trench semiconductor layers 30 is narrow, an ion implantation regions (that is, regions into which ions are implanted to form the connection regions 52 and the contact region 54) can be provided across multiple inter-trench semiconductor layers 30, so that the width of the ion implantation regions can be ensured to be wide. Therefore, a width of opening portions of an ion implantation mask does not become extremely narrow, and the connection regions 52 and the contact regions 54 can be easily formed.

As described above, according to the switching element of the first embodiment, it is possible to restrict the concentration of the recovery current and the avalanche current at the connection intersection portions 60a. Moreover, according to the switching element of the first embodiment, the channel density can be increased, and a low on-resistance can be achieved. Furthermore, according to the structure of the switching element 10 of the first embodiment, even if the interval between the trenches 14 is narrow, the connection regions 52 and the contact regions 54 can be easily formed.

### Second Embodiment

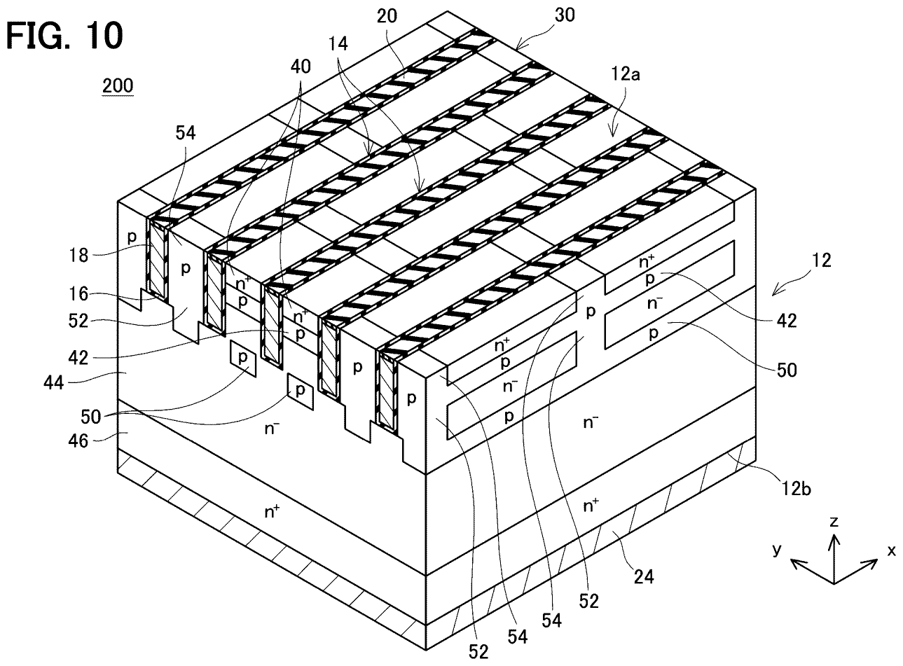

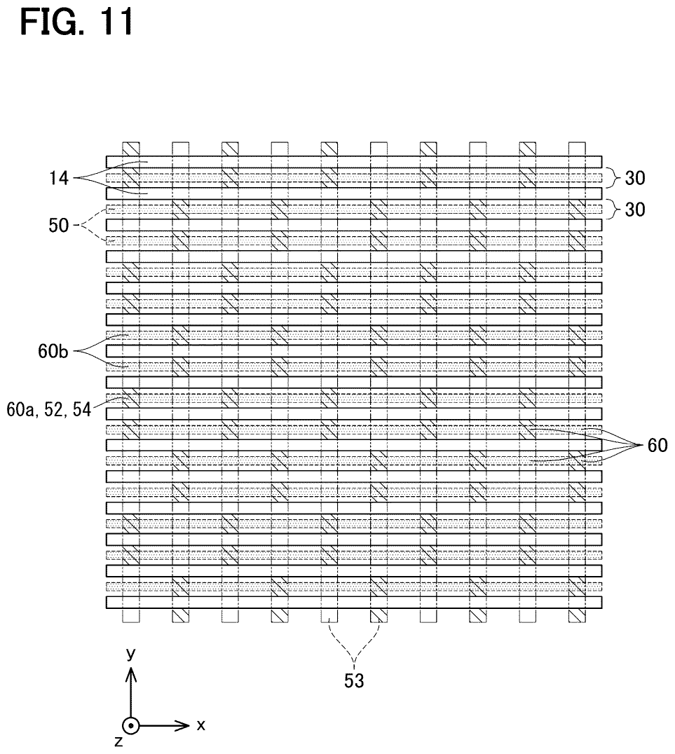

FIG. 10 and FIG. 11 illustrate a switching element 200 according to a second embodiment. In the second embodiment, each of the deep regions 50 extend linearly in the x direction. The deep regions 50 are arranged at intervals in the y direction. The deep regions 50 are disposed below central portions of the respective inter-trench semiconductor layers 30 in the y direction.

Each of the deep regions 50 is connected to the source electrode 22 via the connection regions 52 and the contact regions 54. As illustrated in FIG. 11, the connection regions 52 are arranged to form columns 53 extending linearly in the y direction. The columns 53 are arranged at intervals in the x direction.

As illustrated in FIG. 11, the sets of the connection region 52 and the contact region 54 are provided in a part of the intersection portions 60. The arrangement of the connection intersection portions 60a and the non-connection intersection portions 60b in the second embodiment (that is, the arrangement in terms of the cell) is the same as the arrangement in the first embodiment (that is, the arrangement shown in FIG. 7). That is, the connection intersection portions 60a and the non-connection intersection portions 60b are arranged so as to satisfy the conditions (i) to (iv) described above. Therefore, also in the second embodiment, it is possible to restrict the concentration of the recovery current and the avalanche current while ensuring a wide channel. Also in the second embodiment, when the interval between the trenches 14 is narrow, the connection regions 52 and the contact regions 54 can be easily formed.

### Third Embodiment

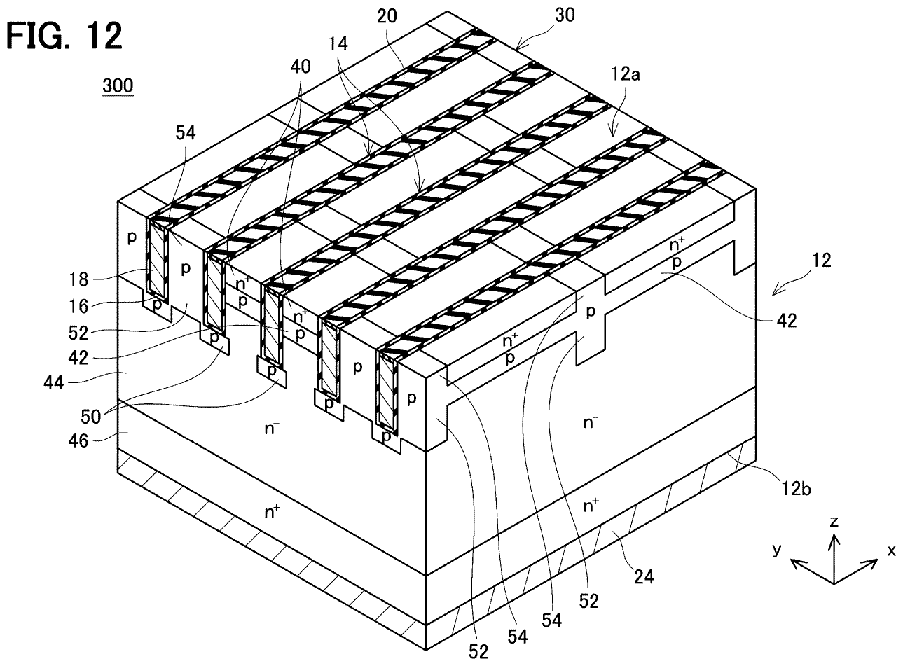

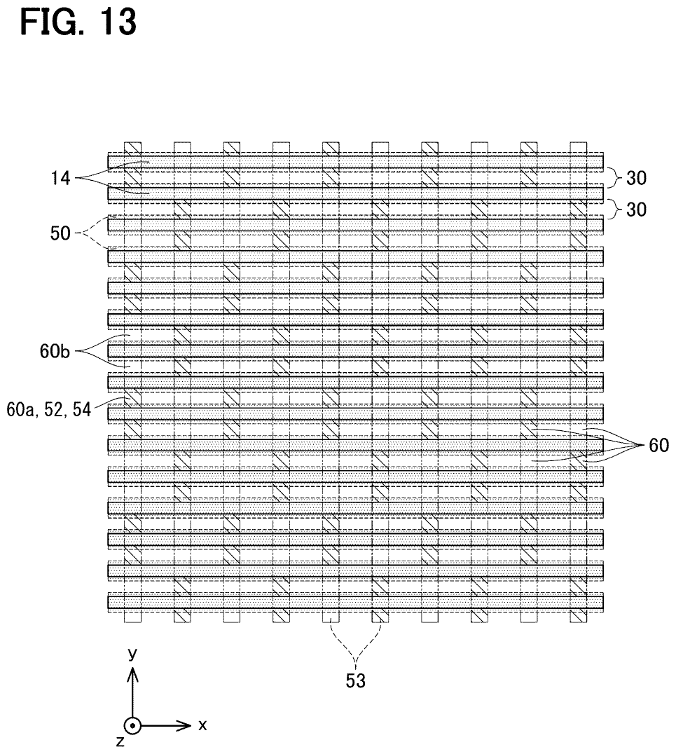

FIG. 12 and FIG. 13 illustrate a switching element 300 according to a third embodiment. In the third embodiment, each of the deep regions 50 extends linearly in the x direction. The deep regions 50 are arranged at intervals in the y direction. The deep regions 50 are disposed below the respective trenches 14.

Each of the deep regions 50 is connected to the source electrode 22 via the connection regions 52 and the contact regions 54. As illustrated in FIG. 13, the connection regions 52 are arranged to form columns 53 extending linearly in the y direction. The columns 53 are arranged at intervals in the x direction.

As illustrated in FIG. 13, the sets of the connection region 52 and the contact region 54 are provided in a part of the intersection portions 60. The arrangement of the connection intersection portions 60a and the non-connection intersection portions 60b in the third embodiment (that is, the arrangement in terms of the cell) is the same as the arrangement in the first embodiment (that is, the arrangement shown in FIG. 7). That is, the connection intersection portions 60a and the non-connection intersection portions 60b are arranged so as to satisfy the conditions (i) to (iv) described above. Therefore, in the third embodiment as well, it is possible to restrict the concentration of the recovery current and the avalanche current while ensuring a wide channel. Also in the third embodiment, when the interval between the trenches 14 is narrow, the connection regions 52 and the contact regions 54 can be easily formed.

### Fourth Embodiment

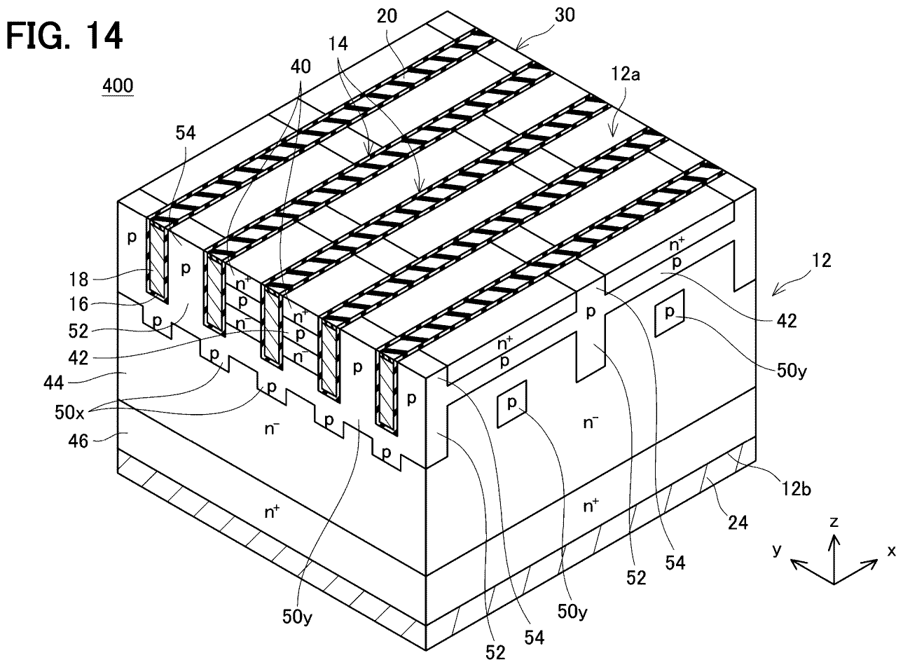

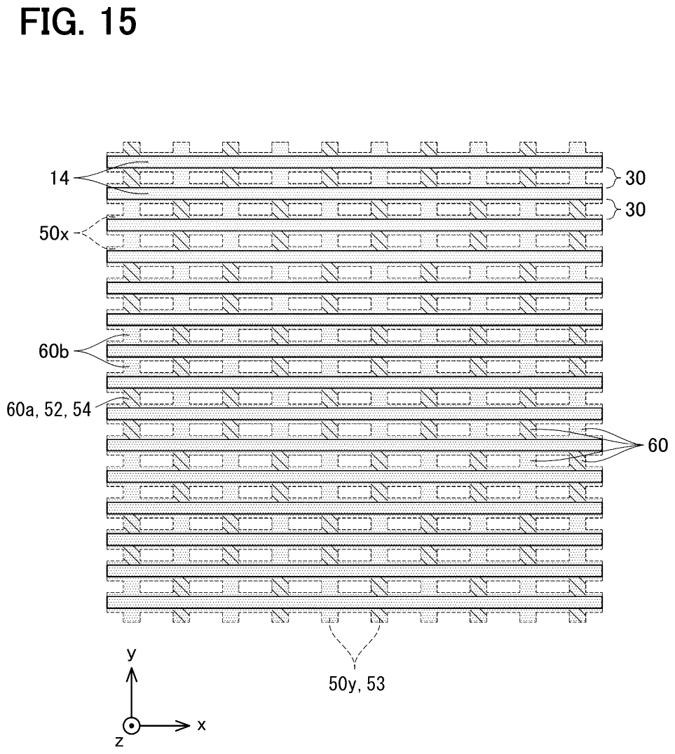

FIG. 14 and FIG. 15 illustrate a switching element 400 according to a fourth embodiment. The switching element 400 of the fourth embodiment has two types of deep regions 50x and 50y. Each of the deep regions 50y extends linearly in the y direction. The deep regions 50y are arranged at intervals in the x direction. Each of the deep regions 50y is disposed at a depth including the lower ends of the trenches 14. Each of the deep regions 50x is disposed below each of the deep regions 50y. Each of the deep regions 50x extends linearly in the x direction. The deep regions 50x are arranged at intervals in the y direction. An upper end portion of each of the deep regions 50x is disposed at a depth overlapping a lower end portion of each of the deep regions 50y. Each of the deep regions 50x and each of the deep regions 50y are connected to each other at a point where they intersect with each other.

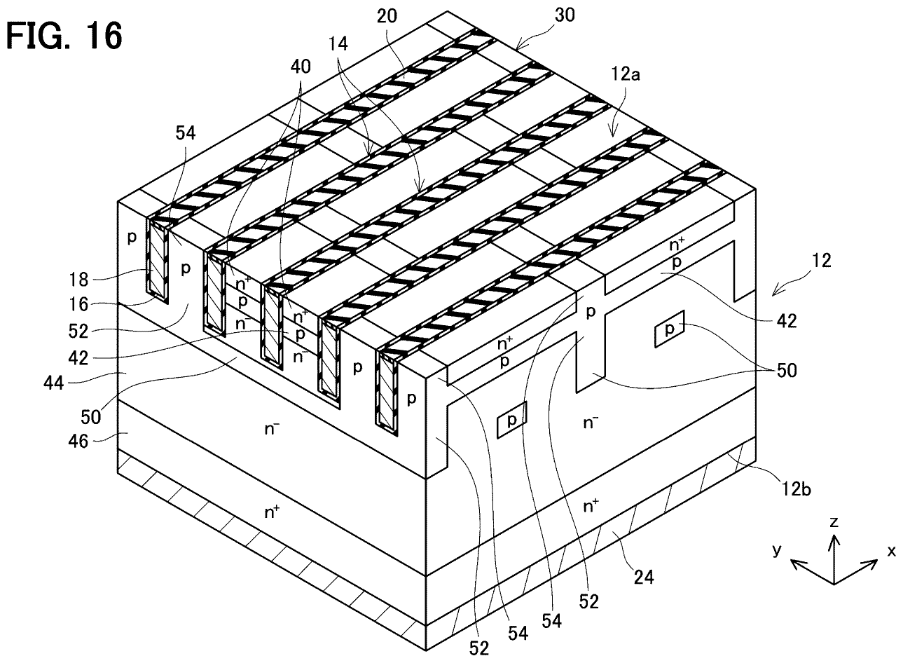

Each of the deep regions 50y is connected to the source electrode 22 via the connection regions 52 and the contact regions 54. As illustrated in FIG. 15, the connection regions 52 are arranged to form columns 53 extending linearly in the y direction. In FIG. 16, the columns 53 extending in the y direction overlap the deep regions 50y. The columns 53 are arranged at intervals in the x direction.

As illustrated in FIG. 15, the sets of the connection region 52 and the contact region 54 are provided in a part of the intersection portions 60. The arrangement of the connection intersection portions 60a and the non-connection intersection portions 60b in the fourth embodiment (that is, the arrangement in terms of the cell) is the same as the arrangement in the first embodiment (that is, the arrangement shown in FIG. 7). That is, the connection intersection portions 60a and the non-connection intersection portions 60b are arranged so as to satisfy the conditions (i) to (iv) described above. Therefore, in the fourth embodiment as well, it is possible to restrict the concentration of the recovery current and the avalanche current while ensuring a wide channel. Also in the fourth embodiment, when the interval between the trenches 14 is narrow, the connection regions 52 and the contact regions 54 can be easily formed.

In addition, in the fourth embodiment, the deep regions 50x and 50y extend along the x direction and the y direction, respectively. Thus, the deep regions 50x, 50y in of the each non-connection intersection portion 60b are connected to the closest connection regions 52 by a shorter current path. Therefore, the potentials of the deep regions 50x and 50y can be made more stable.

In the above-described fourth embodiment, the deep regions 50y are disposed above the deep regions 50x. However, the deep regions 50x may be disposed above the deep regions 50y. Alternatively, the deep region 50x and the deep region 50y may be arranged at the same depth.

In the first to fourth embodiments described above, each of the deep regions 50 is disposed at a depth including the lower ends of the trenches 14. Alternatively, each of the deep regions 50 may be disposed below the lower ends of the trenches 14. For example, in the first embodiment, each of the deep regions 50 may be disposed below the lower ends of the trenches 14 as illustrated in FIG. 16.

In the first to fourth embodiments described above, the contact regions 54 are disposed above the connection regions 52. However, the positions of the connection regions 52 and the contact regions 54 may be shifted in the x direction. The number of the connection regions 52 and the number of the contact regions 54 may be different from each other.

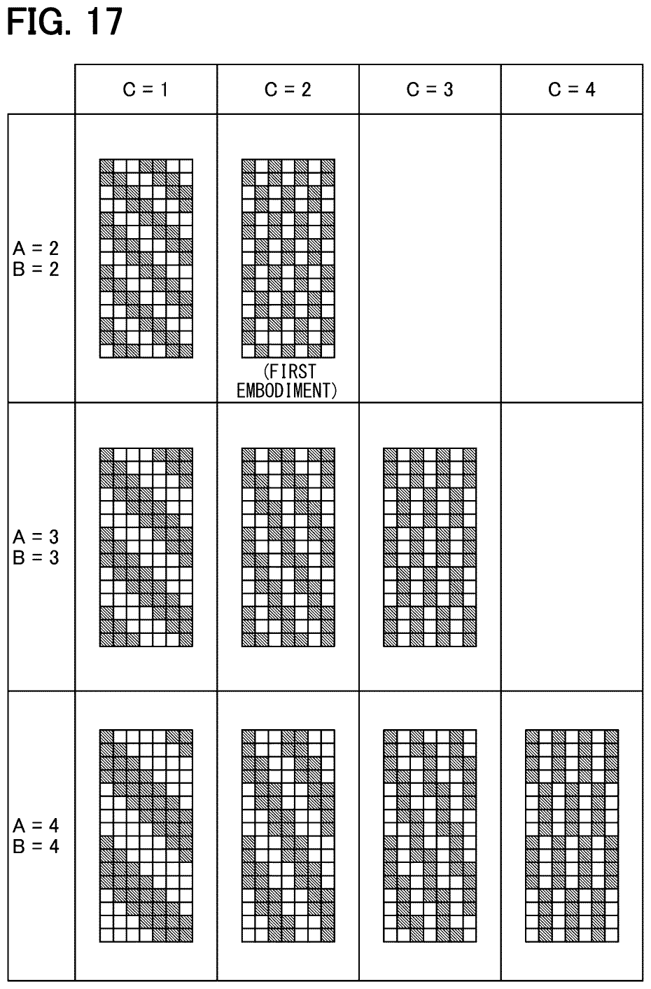

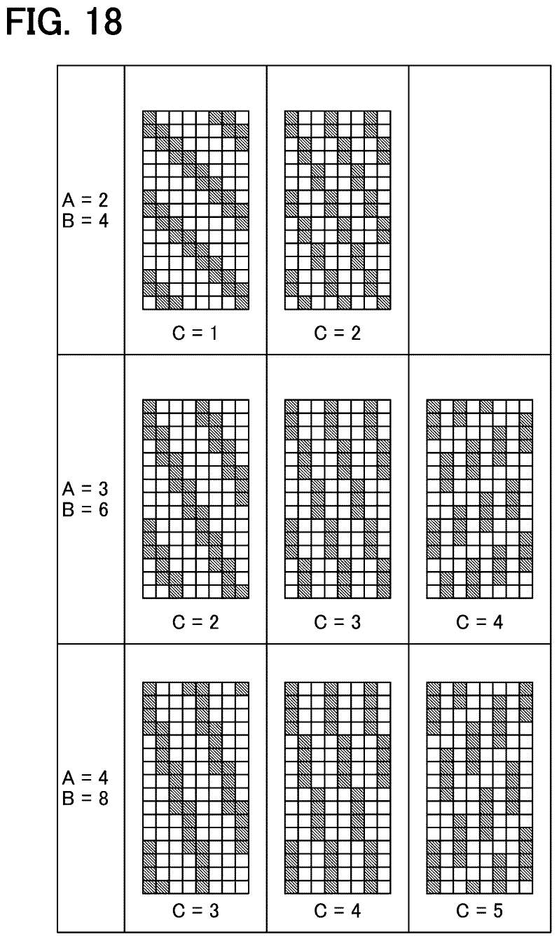

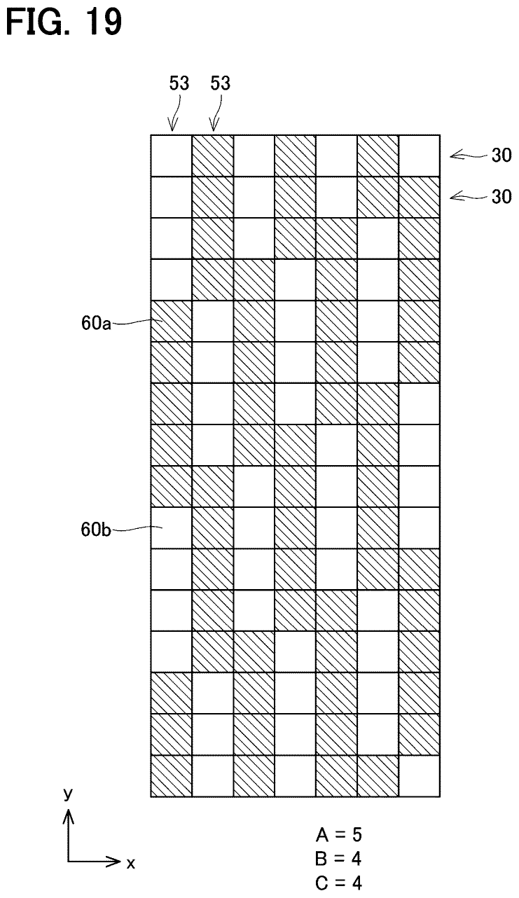

In the above-described first to fourth embodiments, the connection intersection portions 60a and the non-connection intersection portions 60b are arranged as shown in FIG. 7. However, as long as the above-described conditions (i) to (iv) are satisfied, the connection intersection portions 60a and the non-connection intersection portions 60b may be arranged in any manner. FIG. 17 shows an example of an arrangement that satisfies conditions (i) to (iv) when the first reference number A and the second reference number B are equal to each other. FIG. 18 shows an example of an arrangement that satisfies conditions (i) to (iv) when the first reference number A is smaller than the second reference number B. In FIG. 17 and FIG. 18, the horizontal direction is the x direction, the vertical direction is the y direction, cells hatched with oblique lines are the connection intersection portions 60a, and blank cells are the non-connection intersection portions 60b. FIG. 19 shows an example of an arrangement that satisfies conditions (i) to (iv) when the first reference number A is greater than the second reference number B.

As illustrated in FIG. 17 and FIG. 18, when the second reference number B is equal to or greater than the first reference number A, the non-connection intersection portions 60b (that is, the channels) can be made wide, and the on-resistance of the switching element can be effectively reduced.

Furthermore, as illustrated in FIG. 17 and FIG. 18 (excluding A=4, B=4, and C=1 in FIG. 17), when the number of the connection intersection portions 60a that are arranged continuously in the x direction is 3 or less, the congestion of the connection intersection portions 60a can be more effectively restricted. Therefore, each of the connection intersection portions 60a contributes to stabilizing the potential of the deep regions 50, and it is possible to reduce unnecessary connection intersection portions 60a. Therefore, the non-connection intersection portion 60b (that is, the channels) can be made wide, and the on-resistance of the switching element can be effectively reduced.

In FIG. 17 and FIG. 18, when the arrangement is set in such a manner that (A, B, C) is (2, 2, 2), (3, 3, 3), (4, 4, 4), (2, 4, 2), (3, 6, 3), (3, 6, 4), (4, 8, 4), or (4, 8, 5), there is no location where the connection intersection portions 60a are continuous in the x direction. As shown by these examples, a configuration in which there are no portions where the connection intersection portions 60a are continuous in the x-direction allows the connection intersection portions 60a to be arranged in a more dispersed manner, and makes it possible to more effectively restrict the concentration of current at the connection intersection portions 60a.

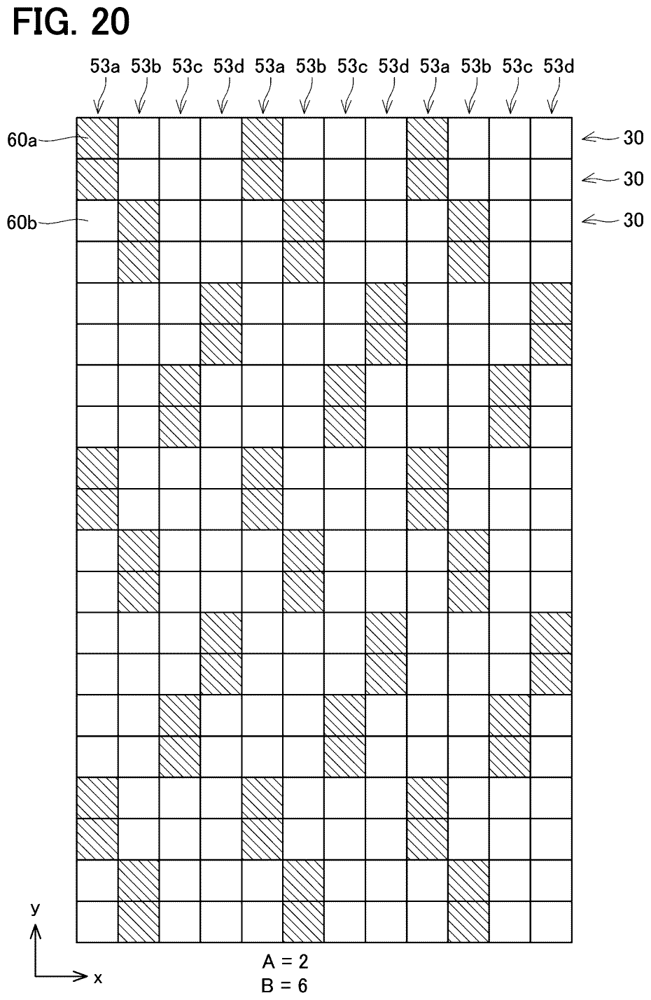

In FIG. 17, FIG. 18, and FIG. 19, the connection intersection portions 60a and the non-connection intersection portions 60b are arranged in such a manner that the phase of the repeating pattern is shifted downward by a constant amount (that is, the shift amount C) as the column shifts rightward, but the shift amount of the phase of the repeating pattern does not have to be constant. For example, as shown in FIG. 20, the shift amount of the phase may change depending on the position. In FIG. 20, the first reference number A is 2 and the second reference number B is 6 (that is, 3A). Further, the shift amount of the column 53b with respect to the column 53a is 2, the shift amount of the column 53c with respect to the column 53b is 4, and the shift amount of the column 53d with respect to the column 53c is −2. In other words, the shift amount of the column 53b with respect to the column 53a is 2 (that is, A), the shift amount of the column 53c with respect to the column 53a is 6 (that is, 3A), and the shift amount of the column 53d with respect to the column 53a is 4 (that is, 2A). In FIG. 20, the phase shift amount changes in such a four-column cycle. By changing the phase shift amount in this manner, it may be possible to more evenly distribute the connection intersection portions 60a and the non-connection intersection portions 60b. Even if the first reference number A is different from that shown in FIG. 20, the second reference number B and each shift amount can be set at the above ratio.

The x direction in the above-described embodiments is an example of a first direction. The y direction in the above-described embodiments is an example of a second direction.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve objectives at the same time, and achieving one of the objectives itself has technical usefulness.

What is claimed is:

1. A switching element comprising:
a semiconductor substrate having trenches provided from an upper surface of the semiconductor substrate, the trenches extending linearly in a first direction on the upper surface of the semiconductor substrate, the trenches being arranged at intervals in a second direction that intersects the first direction on the upper surface of the semiconductor substrate;
a gate insulating film covering an inner surface of each of the trenches;
a gate electrode disposed inside each of the trenches and being insulated from the semiconductor substrate by the gate insulating film; and
a source electrode being in contact with the upper surface of the semiconductor substrate, wherein
the semiconductor substrate includes inter-trench semiconductor layers sandwiched between each of the trenches,
each of the inter-trench semiconductor layers includes:
a source region of n-type being in contact with the gate insulating film and the source electrode; and
a body region of p-type being in contact with the gate insulating film at a position below the source region,
the semiconductor substrate further includes:
a drift region of n-type distributed over a lower portion of each of the inter-trench semiconductor layers and being in contact with the gate insulating film at a position below the body region in each of the inter-trench semiconductor layers;
deep regions of p-type disposed in a range surrounded by the drift region, disposed below the body region to be spaced apart from the body region, and disposed in a range including a lower end of each of the trenches or below the lower end of each of the trenches in a thickness direction of the semiconductor substrate; and
connection regions of p-type connecting the body region and the deep regions,
when the semiconductor substrate is viewed from above, the connection regions are arranged linearly at intervals along the second direction to form columns, and the columns are arranged at intervals in the first direction,
when the semiconductor substrate is viewed from above, the inter-trench semiconductor layers intersect the columns at intersection portions, and the intersection portions include connection intersection portions at which the connection regions are disposed and non-connection intersection portions at which the connection regions are not disposed,
the connection intersection portions and the non-connection intersection portions are arranged so as to satisfy following conditions (i) to (iv):
(i) in each of the columns, the connection intersection portions and the non-connection intersection portions are arranged in a pattern in which a portion where the connection intersection portions of a first reference number, which is 2 or greater, are arranged continuously and a portion where the non-connection intersection portions of a second reference number, which is 2 or greater, are arranged continuously are arranged alternately in the second direction;
(ii) a phase of the pattern is shifted in the second direction between adjacent columns in the columns;
(iii) when counting a Chebyshev distance in units of each of the intersection portions, the Chebyshev distance from each of the non-connection intersection portions to a closest one of the connection intersection portions is 1; and
(vi) when counting a Chebyshev distance in units of each of the intersection portions, the Chebyshev distance from each of the connection intersection portions to a closest one of the non-connection intersection portions is 1.

2. The switching element according to claim 1, wherein
the second reference number is equal to or greater than the first reference number.

3. The switching element according to claim 1, wherein
in each of the inter-trench semiconductor layers, the connection intersection portions are not continuous in the first direction when viewed in units of each of the intersection portions.

4. The switching element according to claim 1, wherein
in each of the inter-trench semiconductor layers, a number of the connection intersection portions that are arranged continuously in the first direction is 3 or less when viewed in units of each of the intersection portions.

5. The switching element according to claim 1, wherein
when the first reference number is expressed by any integer A, the second reference number is 3A;
in the columns, the phase of the pattern changes periodically every four columns,
when the four columns are designated as a first column, a second column, a third column, and a fourth column in order, and a shift amount of the phase of the pattern is counted in units of each of the intersection portions, the shift amount of the second column with respect to the first column is A, the shift amount of the third column with respect to the first column is 3A, and the shift amount of the fourth column with respect to the first column is 2A.

6. The switching element according to claim 1, wherein
the deep regions extend linearly along the second direction and are arranged at intervals in the first direction so that the deep regions extend along the columns, respectively, when the semiconductor substrate is viewed from above.

7. The switching element according to claim 1, further comprising
contact regions of p-type disposed above the connection regions and connecting the body region and the source electrode.
